(19) United States
(12) Patent Application Publication
(10) Pub. No.: US 2024/0224655 A1
(43) Pub. Date: Jul. 4, 2024

(54) STRETCHABLE DISPLAY DEVICE

(71) Applicant: Samsung Display Co., LTD., Yongin-si (KR)

(72) Inventors: Jinwoo CHOI, Yongin-si (KR); Daeho SONG, Yongin-si (KR); Hyungil JEON, Yongin-si (KR)

(21) Appl. No.: 18/401,774

(22) Filed: Jan. 2, 2024

(30) Foreign Application Priority Data
Jan. 2, 2023 (KR) 10-2023-0000368

(51) Int. Cl. H10K 59/131; H10K 77/10

(52) U.S. Cl. CPC H10K 59/131; H10K 77/111; H10K 2102/311

(57) ABSTRACT

A stretchable display device includes a plurality of display units each including a light-emitting diode, and a connection unit disposed between two adjacent display units among the plurality of display units and connected to each of the two adjacent display units. The connection unit includes a curved part curved in a direction perpendicular to an upper surface of a display unit of the plurality of display units and a hole is defined in the connection unit when viewed from the direction perpendicular to the upper surface of the display unit of the plurality of display units.

This application claims priority to Korean Patent Application No. 10-2023-0000368, filed on Jan. 2, 2023, and all the benefits accruing therefrom under 35 U.S.C. § 119, the content of which in its entirety is herein incorporated by reference.

### BACKGROUND

### 1. Field

Embodiments relate to a display device, and more particularly, to a stretchable display device.

### 2. Description of the Related Art

According to a development of display devices visually displaying electrical signals, various display devices having excellent characteristics, such as being thin and light weight, and having low power consumption, are being introduced. Recently, flexible display devices that may be folded or rolled into a roll shape are being researched and developed, and furthermore, research and development of stretchable display devices that may be changed into various shapes are being actively conducted.

### SUMMARY

Embodiments include a display device capable of having substantially high stretchability and substantially high contraction. However, these objectives are examples, and are not limited thereto.

Additional features will be set forth in part in the description which follows and, in part, will be apparent from the description, or may be learned by practice of the presented embodiments of the disclosure.

In an embodiment of the disclosure, a stretchable display device includes a plurality of display units each including a light-emitting diode, and a connection unit disposed between two adjacent display units among the plurality of display units and connected to each of the two adjacent display units. The connection unit includes a curved part curved in a direction perpendicular to an upper surface of a display unit of the plurality of display units and a hole is defined in the connection unit when viewed from the direction perpendicular to the upper surface of the display unit of the plurality of display units.

In an embodiment, the connection unit may include a pair of first parts respectively connected to the two adjacent display units, and a second part disposed between the pair of first parts and disposed on a surface different from a surface where each of the pair of first parts is disposed.

In an embodiment, in each of the pair of first parts, a width of an area adjacent to the second part may be greater than a width of an area adjacent to the display unit of the plurality of display units.

In an embodiment, the pair of first parts and the second part may be disposed on different surfaces from a surface where the display unit of the plurality of display units is disposed.

In an embodiment, one of the two adjacent display units may include a sub-pixel circuit electrically connected to the light-emitting diode of the one display unit and including a thin-film transistor and a capacitor, and a plurality of lines electrically connected to the sub-pixel circuit and providing signals or voltages may extend toward another one of the two adjacent display units by passing the connection unit.

In an embodiment, the plurality of lines may include a first line and a second line, and the first line and the second line may be disposed on opposite sides with respect to the hole of the connection unit.

In an embodiment, a shape of the connection unit may be changed to reduce a curvature of the curved part when the stretchable display device is extended.

In an embodiment, the hole of the connection unit may have an elliptical shape.

In an embodiment, a shape of the hole of the connection unit may be changed from the elliptical shape to a circular shape when the stretchable display device is extended.

In an embodiment of the disclosure, a stretchable display device includes a substrate including a plurality of first areas and a second area between two adjacent first areas among the plurality of first areas, a plurality of display units respectively corresponding to the plurality of first areas of the substrate and each including a light-emitting diode disposed in corresponding one of the plurality of first areas, and a connection unit corresponding to the second area of the substrate. The connection unit includes a curved part curved in a direction perpendicular to an upper surface of a display unit of the plurality of display units and a hole is defined in the connection unit when viewed from the direction perpendicular to the upper surface of the display unit of the plurality of display units.

In an embodiment, the second area of the substrate may include a curved part curved in the direction perpendicular to the upper surface of the display unit of the plurality of display units and a hole corresponding to the hole of the connection unit may be defined in the second area of the substrate when viewed from the direction perpendicular to the upper surface of the display unit of the plurality of display units.

In an embodiment, the connection unit may include a pair of first parts respectively connected to the two adjacent display units of the plurality of display units, and a second part disposed between the pair of first parts and disposed on a surface different from a surface where each of the pair of first parts is disposed.

In an embodiment, in each of the pair of first parts, a width of an area adjacent to the second part may be greater than a width of an area adjacent to the display unit of the plurality of display units.

In an embodiment, any one of the two adjacent display units may include a sub-pixel circuit electrically connected to the light-emitting diode of the one display unit and including a thin-film transistor and a capacitor.

In an embodiment, the connection unit may include a plurality of lines disposed in the second area of the substrate, electrically connected to the sub-pixel circuit, and providing signals or voltages.

In an embodiment, the plurality of lines may include a first line and a second line, and the first line and the second line may be disposed on opposite sides with respect to the hole of the connection unit.

In an embodiment, a shape of the connection unit may be changed to reduce a curvature of the curved part when the stretchable display device is extended.

In an embodiment, the hole of the connection unit may have an elliptical shape.

In an embodiment, a shape of the hole of the connection unit may be changed from the elliptical shape to a circular shape when the stretchable display device is extended.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a perspective view of an embodiment of a display device;

FIG. 2 is a plan view of a part of the display device of FIG. 1;

FIG. 3 is a side view of a part of the display device of FIG. 1;

FIG. 4 is a plan view illustrating a display device in a state where a force for stretching the display device is applied;

FIG. 5 illustrates side views of an embodiment of a display device in a state where a force for stretching the display device is applied;

FIG. 6 is an equivalent circuit diagram schematically illustrating an embodiment of a light-emitting diode disposed in a display unit of a display device and a sub-pixel circuit electrically connected to the light-emitting diode;

FIG. 7 is a plan view illustrating an embodiment of a display unit of a display device and connection units connected to the display unit;

FIG. 8 is a cross-sectional view of the display unit taken along line VIII-VIII′ of FIG. 7;

FIG. 9 is a cross-sectional view of the connection unit taken along line IX-IX′ of FIG. 7; and

FIG. 10 is a plan view schematically illustrating an embodiment of a display device.

### DETAILED DESCRIPTION

Reference will now be made in detail to embodiments, illustrative examples of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will be omitted.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or component is referred to as being formed on another layer, region, or component, it can be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following embodiments are not limited thereto.

When an illustrative embodiment may be implemented differently, a specific process order may be performed differently from the described order. For example, two consecutively described processes may be performed substantially at the same time or performed in an order opposite to the described order.

It will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

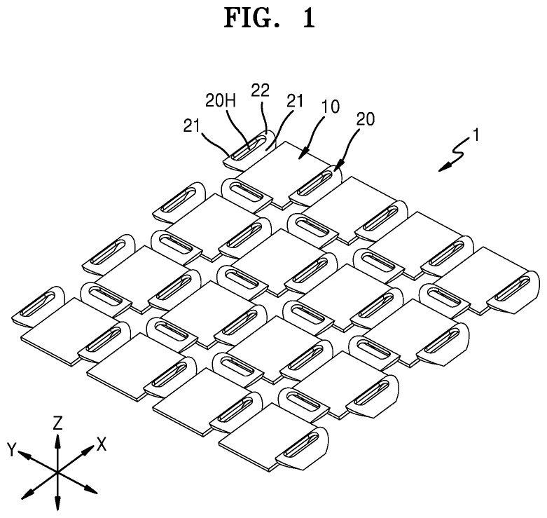

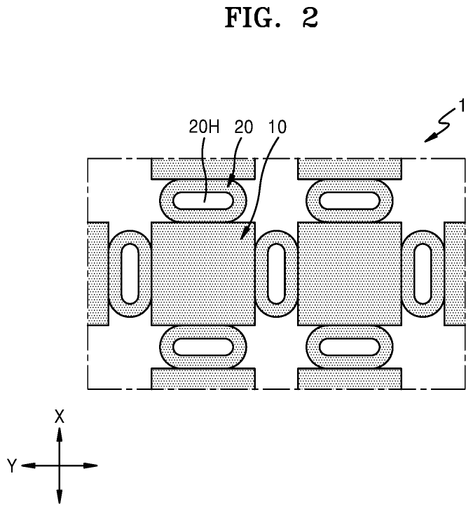

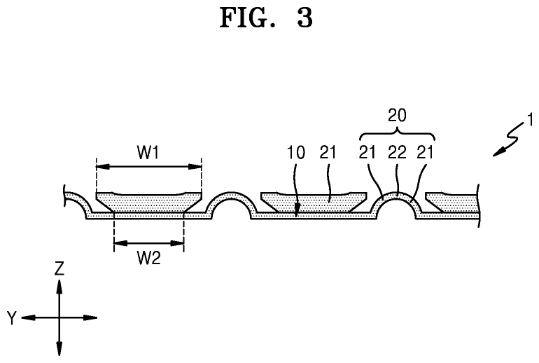

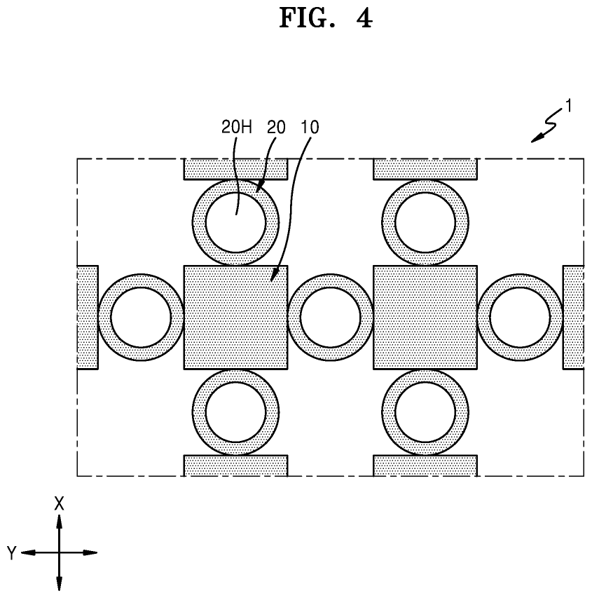

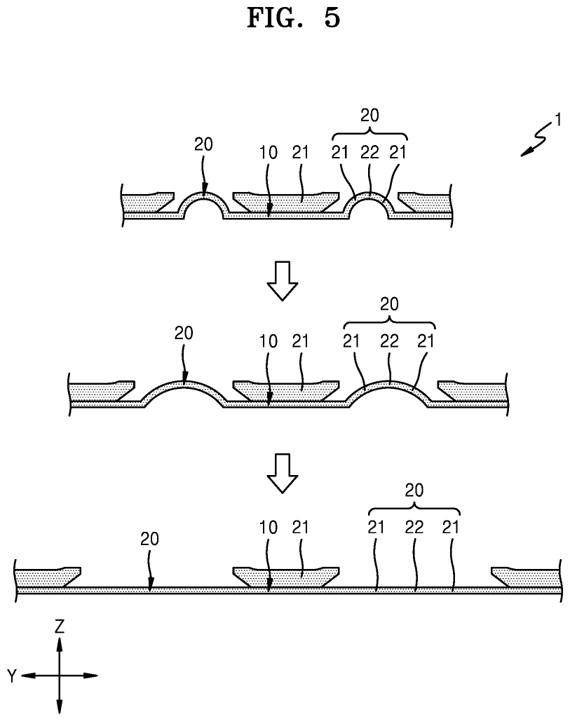

FIG. 1 is a perspective view of an embodiment of a display device 1, FIG. 2 is a plan view of a part of the display device 1 of FIG. 1, FIG. 3 is a side view of a part of the display device 1 of FIG. 1, and FIGS. 4 and 5 are respectively a plan view and a side view illustrating an embodiment of a display device 1 in a state where a force for stretching the display device 1 is applied.

Referring to FIGS. 1 to 3, a stretchable display device 1 (hereinafter also referred to as a display device) may include a display unit (or a display portion) 10 capable of display an image, and a connection unit (or a connection portion) 20 connected to the display unit 10. The display unit 10 may emit light of a predetermined color by light-emitting diodes included in the display unit 10, and the display device 1 may display an image by light emitted by display units 10. The connection unit 20 is an area where the light-emitting diodes are not arranged, and may connect the display units 10 which are spatially spaced apart from each other. In an embodiment, the connection unit 20 may be disposed between two adjacent display units 10 to structurally connect the two adjacent display units 10, for example.

In an embodiment, FIGS. 1 and 2 show that the display unit 10 has a substantially quadrangular shape in a plan view (or when viewed in a direction substantially perpendicular to an upper surface of the display unit 10), but the disclosure is not limited thereto. In another embodiment, the display unit 10 may have a polygonal shape, such as a triangular shape, a pentagonal shape, a hexagonal shape, or the like, or may have a circular shape or an elliptical shape in a plan view.

In an embodiment, FIGS. 1 and 2 show that the display units 10 are arranged in a first direction (e.g., a ±X direction) and a second direction (e.g., +Y direction), but the disclosure is not limited thereto. In an embodiment, the display units 10 may be spaced apart from each other to have various arrangements, such as a radial shape or a honeycomb shape, for example.

The connection unit 20 may have a curved shape in a direction (e.g., a ±Z direction) perpendicular to the upper surface of the display unit 10. In an embodiment, as shown in FIGS. 1 and 3, the connection unit 20 may have a convexly curved shape in the direction (e.g., the +Z direction) perpendicular to the upper surface of the display unit 10, for example. Although not illustrated in the drawings, in another embodiment, the connection unit 20 may have a concavely curved shape in the direction (e.g., the +Z direction) perpendicular to the upper surface of the display unit 10. Hereinafter, for convenience of description, a case where the connection unit 20 has a convexly curved shape in the direction (e.g., the +Z direction) perpendicular to the upper surface of the display unit 10 is described.

As shown in FIGS. 1 and 3, the connection unit 20 may be connected to the display units 10 arranged on opposite sides of the connection unit 20. The connection unit 20 may include first parts 21 disposed on a plane different from that of the display unit 10, and a second part 22 disposed between the first parts 21 and disposed on a plane different from that of the display unit 10. The second part 22 may be disposed on a plane different from that of each of the first parts 21. In an embodiment, the second part 22 may be disposed at a top part of the connection unit 20, and each of the first parts 21 may connect the upper surface of the display unit 10, which is disposed at a relatively lower position than the second part 22, and the second part 22 to each other, for example.

Each of the first parts 21 may be disposed on a surface different from the upper surface of the display unit 10 and a surface where the second part 22 is disposed. Referring to FIG. 3, in a side view, the first part 21 may have a shape in which a first width W1 of an area close to the second part 22 is greater than a second width W2 of an area close to the display unit 10. The first parts 21 and the second part 22 have a structure in which the first parts 21 and the second part 22 are unitary with each other or connected to each other, and as shown in FIG. 3, the connection unit 20 may have a curved shape in the direction (e.g., the +Z direction) perpendicular to the upper surface of the display unit 10.

A hole 20H defined in the second part 22 may be defined in the connection unit 20. As shown in FIGS. 1 and 2, the hole 20H may have a rounded shape with non-uniform curvature. In an embodiment, the hole 20H may have a substantially elliptical shape in a plan view, for example. The connection unit 20 has the hole 20H as described above, and thus stress and/or deformation rate may be reduced when the display device 1 is extended or stretched.

When a force for stretching the display device 1 is applied, as shown in FIGS. 4 and 5, the shape of the connection unit 20 may be changed, and a distance between the display units 10 may increase.

In a plan view, when a force for stretching the display device 1 is applied, the distance between the display units 10 may be changed as the shape of the connection unit 20 is changed. In an embodiment, the hole 20H of the connection unit 20, which has an elliptical shape shown in FIG. 2, may be transformed into a circular shape having a substantially uniform curvature as shown in FIG. 4. In a side view, as shown in FIG. 3, the shape of the connection unit 20 may be changed as shown in FIG. 5 to reduce the curvature, for example. Referring to FIG. 5, when the display device 1 is extended, the radius of curvature of the curved shape of the connection unit 20, which is viewed from the side, may increase (or the curvature may decrease), and when the display device 1 is extended by a greater force, the connection unit 20 may be changed into a substantially flat shape (or the curvature becomes zero).

When the display device 1 is stretched, the structure described above may be changed. In an embodiment, in a plan view, the shape of the hole 20H of the connection unit 20 may be changed from a shape (e.g., a circular shape) having an approximately uniform curvature to a shape (e.g., an elliptical shape) with non-uniform curvature, and in a side view, the connection unit 20 may be changed in a direction in which flatness thereof decreases (e.g., from a flat shape to a curved shape), for example.

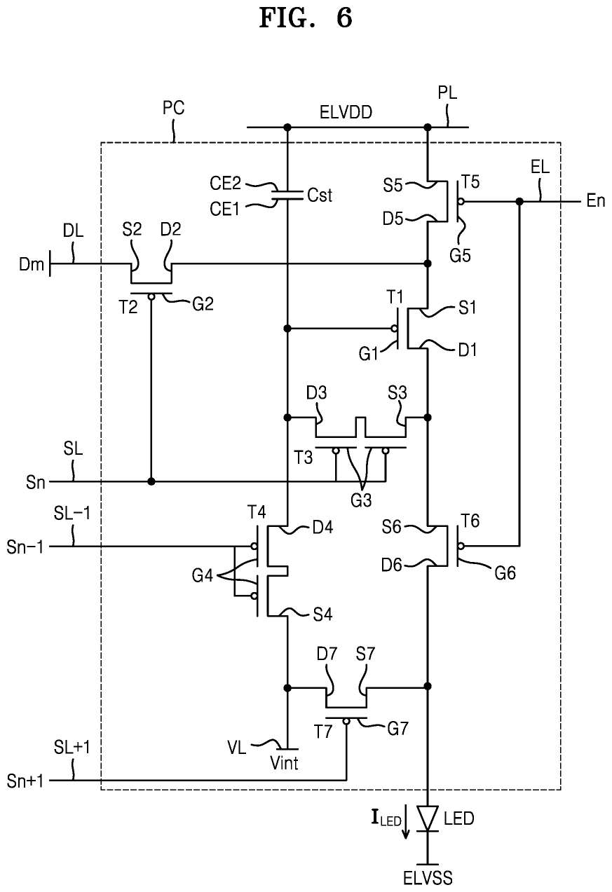

FIG. 6 is an equivalent circuit diagram schematically illustrating an embodiment of a light-emitting diode LED disposed in a display unit 10 of a display device 1 and a sub-pixel circuit PC electrically connected to the light-emitting diode LED. As described above, a light-emitting diode LED may be disposed in the display unit 10 (refer to FIG. 1), and the light-emitting diode LED may be electrically connected to a sub-pixel circuit PC, as shown in FIG. 6.

Referring to FIG. 6, the sub-pixel circuit PC may include a plurality of thin-film transistors and a storage capacitor. The plurality of thin-film transistors and the storage capacitor may be connected to signal lines SL, SL−1, SL+1, EL, and DL, an initialization voltage line VL, and a driving voltage line PL.

The plurality of thin-film transistors may include a driving thin-film transistor (“TFT”) T1, a switching TFT T2, a compensation TFT T3, a first initialization TFT T4, an operation control TFT T5, an emission control TFT T6, and a second initialization TFT T7.

The signal lines SL, SL−1, SL+1, EL, and DL may include a scan line SL which transmits a scan signal Sn, a previous scan line SL−1 which transmits a previous scan signal Sn−1 to the first initialization TFT T4, a following scan line SL+1 which transmits the following scan signal Sn+1 to the second initialization TFT T7, an emission control line EL which transmits an emission control signal En to the operation control TFT T5 and the emission control TFT T6, and a data line DL crossing the scan line SL and which transmits a data signal Dm. The driving voltage line PL may transmit a first power supply ELVDD to the driving TFT T1, and the initialization voltage line VL may transmit an initialization voltage Vint to the first initialization TFT T4 and the second initialization TFT T7.

A driving gate electrode G1 of the driving TFT T1 is connected to a lower electrode CE1 of a storage capacitor Cst, a driving source electrode S1 of the driving TFT T1 is connected to the driving voltage line PL via the operation control TFT T5, and a driving drain electrode D1 of the driving TFT T1 is electrically connected to a first electrode of the light-emitting diode LED via the emission control TFT T6. The driving TFT T1 receives the data signal Dm according to a switching operation of the switching TFT T2 and supplies a driving current LIED to the light-emitting diode LED.

A switching gate electrode G2 of the switching TFT T2 is connected to the scan line SL, a switching source electrode S2 of the switching TFT T2 is connected to the data line DL, and a switching drain electrode D2 of the switching TFT T2 is connected to the driving voltage line PL via the operation control TFT T5 while being connected to the driving source electrode S1 of the driving TFT T1. The switching TFT T2 is turned on according to the scan signal Sn received through the scan line SL and performs a switching operation of transmitting the data signal Dm transmitted to the data line DL to the driving source electrode S1 of the driving TFT T1.

A compensation gate electrode G3 of the compensation TFT T3 is connected to the scan line SL, a compensation source electrode S3 of the compensation TFT T3 is connected to the first electrode of the light-emitting diode LED via the emission control TFT T6 while being connected to the driving drain electrode D1 of the driving TFT T1, and a compensation drain electrode D3 of the compensation TFT T3 is connected to the lower electrode CE1 of the storage capacitor Cst, a first initialization drain electrode D4 of the first initialization TFT T4, and the driving gate electrode G1 of the driving TFT T1. The compensation TFT T3 is turned on according to the scan signal Sn received through the scan line SL and electrically connects the driving gate electrode G1 to the driving drain electrode D1 of the driving TFT T1 to diode-connect the driving TFT T1.

A first initialization gate electrode G4 of the first initialization TFT T4 is connected to the previous scan line SL−1, a first initialization source electrode S4 of the first initialization TFT T4 is connected to the initialization voltage line VL, and the first initialization drain electrode D4 of the first initialization TFT T4 is connected to the lower electrode CE1 of the storage capacitor Cst, the compensation drain electrode D3 of the compensation TFT T3, and the driving gate electrode G1 of the driving TFT T1. The first initialization TFT T4 is turned on according to the previous scan signal Sn−1 received through the previous scan line SL−1 and transmits the initialization voltage Vint to the driving gate electrode G1 of the driving TFT T1 to perform an initialization operation of initializing a voltage of the driving gate electrode G1 of the driving TFT T1.

An operation control gate electrode G5 of the operation control TFT T5 is connected to the emission control line EL, an operation control source electrode S5 of the operation control TFT T5 is connected to the driving voltage line PL, and an operation control drain electrode D5 of the operation control TFT T5 is connected to the driving source electrode S1 of the driving TFT T1 and the switching drain electrode D2 of the switching TFT T2.

An emission control gate electrode G6 of the emission control TFT T6 is connected to the emission control line EL, an emission control source electrode S6 of the emission control TFT T6 is connected to the driving drain electrode D1 of the driving TFT T1 and the compensation source electrode S3 of the compensation TFT T3, and an emission control drain electrode D6 of the emission control TFT T6 is electrically connected to a second initialization source electrode S7 of the second initialization TFT T7 and the first electrode of the light-emitting diode LED.

The operation control TFT T5 and the emission control TFT T6 are turned on at the same time point according to the emission control signal En received through the emission control line EL, and the first power supply ELVDD is transmitted to the light-emitting diode LED to allow the driving current LIED flows through the light-emitting diode LED.

A second initialization gate electrode G7 of the second initialization TFT T7 is connected to the following scan line SL+1, the second initialization source electrode S7 of the second initialization TFT T7 is connected to the emission control drain electrode D6 of the emission control TFT T6 and the first electrode of the light-emitting diode LED, and a second initialization drain electrode D7 of the second initialization TFT T7 is connected to the first initialization source electrode S4 of the first initialization TFT T4 and the initialization voltage line VL.

As the scan line SL and the following scan line SL+1 are electrically connected to each other, the same scan signal Sn may be applied to the scan line SL and the following scan line SL+1. Accordingly, the second initialization TFT T7 may be turned on according to the scan signal Sn received through the following scan line SL+1 and perform an operation of initializing a voltage of the first electrode of the light-emitting diode LED.

An upper electrode CE2 of the storage capacitor Cst is connected to the driving voltage line PL, and a second electrode of the light-emitting diode LED is connected to a line supplying a second power supply ELVSS. Accordingly, the light-emitting diode LED may display an image by emitting light by receiving the driving current I_{LED} from the driving TFT T1.

Although FIG. 6 illustrates each of the compensation TFT T3 and the first initialization TFT T4 have dual gate electrodes, the compensation TFT T3 and the first initialization TFT T4 may each have one gate electrode.

FIG. 6 illustrates that the sub-pixel circuit PC includes seven thin-film transistors and one storage capacitor, but the disclosure is not limited thereto. The number of thin-film transistors and storage capacitors may be variously changed, such as six or less or eight or more, depending on the design of the sub-pixel circuit PC.

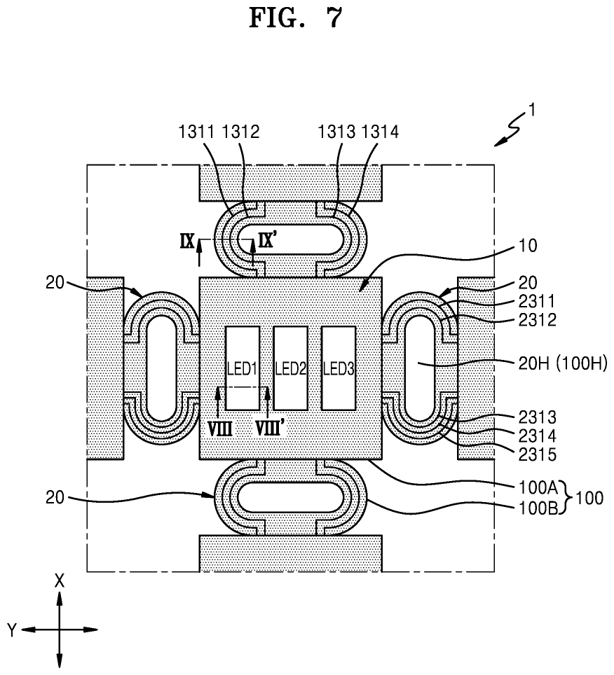

FIG. 7 is a plan view illustrating an embodiment of the display unit 10 of the display device 1 and connection units 20 connected to the display unit 10.

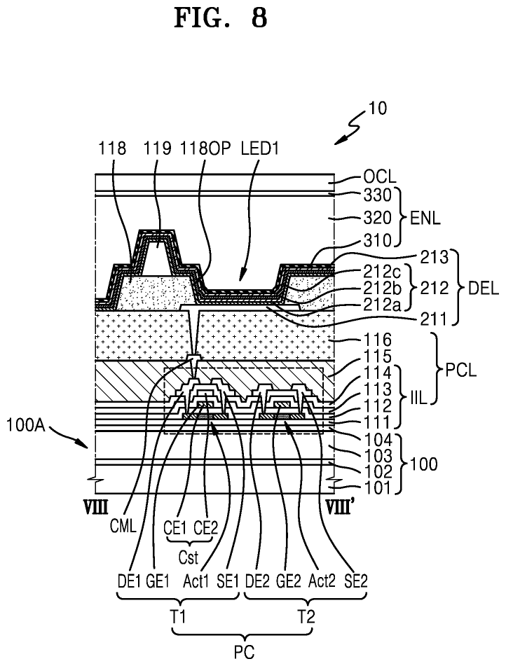

Referring to FIG. 7, light-emitting diodes, e.g., first to third light-emitting diodes LED1, LED2, and LED3, may be arranged in the display unit 10 of the display device 1. The first to third light-emitting diodes LED1, LED2, and LED3 may respectively correspond to first to third sub-pixels emitting different colors of light. The first to third light-emitting diodes LED1, LED2, and LED3 may respectively correspond to sub-pixels emitting red, green, and blue light. As described above with reference to FIG. 6, the first to third light-emitting diodes LED1, LED2, and LED3 may respectively be electrically connected to sub-pixel circuits. In an embodiment, the first light-emitting diode LED1 may be electrically connected to a corresponding sub-pixel circuit, the second light-emitting diode LED2 may be electrically connected to a corresponding sub-pixel circuit, and the third light-emitting diode LED3 may be electrically connected to a corresponding sub-pixel circuit, for example. Although the sub-pixel circuits described above are not shown in FIG. 7, the sub-pixel circuits may be disposed in the display unit 10. In an embodiment, the sub-pixel circuits may respectively be disposed below the first to third light-emitting diodes LED1, LED2, and LED3 to overlap the first to third light-emitting diodes LED1, LED2, and LED3, respectively. The structure of the sub-pixel circuits is described below with reference to FIG. 8, for example.

First to third sub-pixel circuits arranged in each display unit 10 may be electrically connected to a line providing signals and/or voltages. A signal line and/or voltage line electrically connected to the first to third sub-pixel circuits of any one display unit 10 may be electrically connected to the first to third sub-pixel circuits arranged in another display unit 10 by passing through the connection unit 20.

Lines electrically connected to the first to third sub-pixel circuits arranged in any one display unit 10 and extending in a second direction (e.g., a ±Y direction), e.g., first to fifth lines 2311, 2312, 2313, 2314, and 2315, may be electrically connected to the first to third sub-pixel circuits arranged in another display unit 10 by passing through the connection unit 20. The first to fifth lines 2311, 2312, 2313, 2314, and 2315 may respectively be the scan line SL, the previous scan line SL−1, the following scan line SL+1, the emission control line EL, and the initialization voltage line VL, which are described with reference to FIG. 6, for example. Some and some other of the first to fifth lines 2311, 2312, 2313, 2314, and 2315 may be disposed opposite to each other with the hole 20H of the connection unit 20 therebetween. In an embodiment, the first and second lines 2311 and 2312 may extend to pass through a first side of the hole 20H, and the third to fifth lines 2313, 2314, and 2315 may extend to pass through a second side (an opposite side of the first side) of the hole 20H, for example.

Lines electrically connected to the first to third sub-pixel circuits arranged in any one display unit 10 and extending in a first direction (e.g., a ±X direction), e.g., sixth to ninth lines 1311, 1312, 1313, and 1314, may be electrically connected to the first to third sub-pixel circuits arranged in another display unit 10 by passing through the connection unit 20. The sixth to ninth lines 1311, 1312, 1313, and 1314 may respectively be the driving voltage line PL and the data line DL described above with reference to FIG. 6, for example. One of the sixth to ninth lines 1311, 1312, 1313, and 1314 may be the driving voltage line PL shared by the first to third sub-pixel circuits, and the others may be data lines DL respectively electrically connected to the first to third sub-pixel circuits.

Some and some other of the sixth to ninth lines 1311, 1312, 1313, and 1314 may be disposed opposite to each other with the hole 20H of the connection unit 20 therebetween. In an embodiment, the sixth and seventh lines 1311 and 1312 may extend to pass through a first side of the hole 20H, and the eight and ninth lines 1313 and 1314 may extend to pass through a second side (an opposite side of the first side) of the hole 20H, for example.

FIG. 8 is a cross-sectional view of the display unit 10 taken along line VIII-VIII′ of FIG. 7. FIG. 8 shows the first light-emitting diode LED1 disposed in the display unit 10 and the sub-pixel circuit PC electrically connected to the first light-emitting diode LED1. Although not illustrated in FIG. 8, a sub-pixel circuit electrically connected to the second light-emitting diode LED2 (refer to FIG. 7) and a sub-pixel circuit electrically connected to the third light-emitting diode LED3 (refer to FIG. 7) may each have the same structure as the sub-pixel circuit PC to be described below with reference to FIG. 8.

Referring to FIG. 8, the display unit 10 may include a substrate 100, a sub-pixel circuit layer PCL, a display element layer DEL, an encapsulation layer ENL, and a transparent organic material layer OCL. In some embodiments, the transparent organic material layer OCL may be omitted.

In an embodiment, the substrate 100 may include a first base layer 101, a first barrier layer 102, a second base layer 103, and a second barrier layer 104. In an embodiment, the first base layer 101, the first barrier layer 102, the second base layer 103, and the second barrier layer 104 may be sequentially stacked. In another embodiment, the substrate 100 may include metal, glass, or the like.

At least one of the first base layer 101 and the second base layer 103 may include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like.

The first barrier layer 102 and the second barrier layer 104 are barrier layers which prevent penetration of external foreign materials, and may each be a single layer or a multi-layer, each including an inorganic material, such as silicon nitride, silicon oxide, or silicon oxynitride.

The sub-pixel circuit layer PCL may be disposed on the substrate 100. The sub-pixel circuit layer PCL may include the sub-pixel circuit PC. The sub-pixel circuit PC may include at least one TFT. In an embodiment, the sub-pixel circuit PC may include the driving TFT T1, the switching TFT T2, and the storage capacitor Cst.

The sub-pixel circuit layer PCL may further include an inorganic insulating layer IIL, a lower organic insulating layer 115, and an organic insulating layer 116, which are disposed below/above the components of the driving TFT T1. The inorganic insulating layer IIL may include a buffer layer 111, a first gate insulating layer 112, a second gate insulating layer 113, and an inter-insulating layer 114. The driving TFT T1 may include a first semiconductor layer Act1, a first gate electrode GE1, a first source electrode SE1, and a first drain electrode DE1.

The buffer layer 111 may be disposed on the substrate 100. The buffer layer 111 may include an inorganic insulating material, such as silicon nitride, silicon oxynitride, or silicon oxide, and may include a single layer or a multi-layer, each including the inorganic insulating material stated above.

The first semiconductor layer Act1 may be disposed on the buffer layer 111. The first semiconductor layer Act1 may include polysilicon. In an alternative embodiment, the first semiconductor layer Act1 may include amorphous silicon, an oxide semiconductor, an organic semiconductor, or the like. The first semiconductor layer Act1 may include a channel area, a drain area, and a source area, and the drain area and the source area are respectively arranged on opposite sides of the channel area.

The first gate electrode GE1 may overlap the channel area. The first gate electrode GE1 may include a low-resistance metal material. The first gate electrode GE1 may include a conductive material including molybdenum (Mo), aluminum (Al), copper (Cu), and/or titanium (Ti), and may include a multi-layer or a single layer, each including the material stated above.

The first gate insulating layer 112 between the first semiconductor layer Act1 and the first gate electrode GE1 may include an inorganic insulating material, such as silicon oxide, silicon nitride, silicon oxynitride, aluminum oxide, titanium oxide, tantalum oxide, hafnium oxide, or zinc oxide.

The second gate insulating layer 113 may cover the first gate electrode GE1. Similar to the first gate insulating layer 112, the second gate insulating layer 113 may include an inorganic insulating material, such as silicon oxide, silicon nitride, silicon oxynitride, aluminum oxide, titanium oxide, tantalum oxide, hafnium oxide, zinc oxide, or the like.

An upper electrode CE2 of the storage capacitor Cst may be disposed on the second gate insulating layer 113. The upper electrode CE2 may overlap the first gate electrode GE1 therebelow. At this time, the first gate electrode GE1 of the driving TFT T1 and the upper electrode CE2, which overlap each other with the second gate insulating layer 113 therebetween, may constitute the storage capacitor Cst. That is, the first gate electrode GE1 of the driving TFT T1 may function as a lower electrode CE1 of the storage capacitor Cst.

In an embodiment, the storage capacitor Cst and the driving TFT T1 may overlap each other. In another embodiment, the storage capacitor Cst may not overlap the driving TFT T1.

The upper electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may include a single layer or a multi-layer, each including the material stated above.

The inter-insulating layer 114 may cover the upper electrode CE2. The inter-insulating layer 114 may include an inorganic insulating material such as silicon oxide, silicon nitride, silicon oxynitride, aluminum oxide, titanium oxide, tantalum oxide, hafnium oxide, zinc oxide, or the like. The inter-insulating layer 114 may include a single layer or a multi-layer, each including the inorganic insulating material stated above.

Each of the first drain electrode DE1 and the first source electrode SE1 may be disposed on the inter-insulating layer 114. The first drain electrode DE1 and the first source electrode SE1 may each include a material having good conductivity. The first drain electrode DE1 and the first source electrode SE1 may each include a conductive material including Mo, Al, Cu, Ti, or the like, and may include a multi-layer or a single layer, each including the above material. In an embodiment, the first drain electrode DE1 and the first source electrode SE1 may each have a multi-layered structure of Ti/Al/Ti.

The switching TFT T2 may include a second semiconductor layer Act2, a second gate electrode GE2, a second drain electrode DE2, and a second source electrode SE2. Because the second semiconductor layer Act2, the second gate electrode GE2, the second drain electrode DE2, and the second source electrode SE2 are respectively similar to the first semiconductor layer Act1, the first gate electrode GE1, the first drain electrode DE1, and the first source electrode SE1, detailed descriptions thereof are omitted.

The lower organic insulating layer 115 may be disposed on the at least one TFT. In an embodiment, the lower organic insulating layer 115 may cover the first drain electrode DE1 and the first source electrode SE1. The lower organic insulating layer 115 may include an organic insulating material. In an embodiment, the lower organic insulating layer 115 may include an organic insulating material, such as a general commercial polymer, such as poly(methyl methacrylate) (“PMMA”) or polystyrene (“PS”), a polymer derivative having a phenol group, an acrylic polymer, an imide polymer, an aryl ether polymer, an amide polymer, a fluorine polymer, a p-xylene polymer, a vinyl alcohol polymer, or any combinations thereof, for example.

A connection electrode CML may be disposed on the lower organic insulating layer 115. At this time, the connection electrode CML may be connected to the first drain electrode DE1 or the first source electrode SE1 through a contact hole in the lower organic insulating layer 115. The connection electrode CML may include a material having good conductivity. The connection electrode CML may include a conductive material including Mo, Al, Cu, Ti, or the like, and may include a multi-layer or a single layer, each including the above material. In an embodiment, the connection electrode CML may have a multi-layered structure of Ti/Al/Ti.

The organic insulating layer 116 may cover the connection electrode CML. The organic insulating layer 116 may include an organic insulating material. The organic insulating layer 116 may include a general commercial polymer such as PMMA or PS, a polymer derivative having a phenol group, an acrylic polymer, an imide polymer, an aryl ether polymer, an amide polymer, a fluorine polymer, a p-xylene polymer, a vinyl alcohol polymer, or any combinations thereof.

The display element layer DEL may be disposed on the sub-pixel circuit layer PCL. The display element layer DEL may include the first to third light-emitting diodes LED1, LED2, and LED3 (refer to FIG. 7), which have been described above with reference to FIG. 7, as display elements. In this regard, FIG. 8 shows the first light-emitting diode LED1.

The first light-emitting diode LED1 may include a first electrode 211, an intermediate layer 212, and a second electrode 213.

The first electrode 211 may be electrically connected to the connection electrode CML through a contact hole in the organic insulating layer 116. The first electrode 211 may include a conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the first electrode 211 may include a reflective film including Ag, Mg, Al, Pt, Pd, Au, Ni, Nd, Ir, Cr, or any combinations thereof. In another embodiment, the first electrode 211 may further include a film including ITO, IZO, ZnO, or In O₃ above/below the reflective film stated above.

A bank layer 118 in which an opening 118OP exposing a central part of the first electrode 211 is defined may be disposed on the first electrode 211. The bank layer 118 may include an organic insulating material and/or an inorganic insulating material. The opening 118OP of the bank layer 118 may define an emission area of light emitted by the first light-emitting diode LED1. In an embodiment, a width of the opening 118OP may correspond to a width of the emission area, for example. Also, the width of the opening 118OP may correspond to a width of a sub-pixel.

A spacer 119 may be disposed on the bank layer 118. The spacer 119 may include an organic material, such as polyimide. In an alternative embodiment, the spacer 119 may include an inorganic insulating material, such as silicon nitride or silicon oxide, or may include an organic insulating material and an inorganic insulating material.

In an embodiment, the spacer 119 may include a material different from that of the bank layer 118. In an embodiment, the bank layer 118 may include a light-blocking material, and the spacer 119 may include a transparent material. In another embodiment, the spacer 119 may include the same material as that of the bank layer 118, for example.

The intermediate layer 212 may be disposed on the bank layer 118. The intermediate layer 212 may include an emission layer 212b disposed in the opening 118OP of the bank layer 118. The emission layer 212b may include a polymer organic material or a low-molecular-weight organic material, which emits light of a predetermined color.

A first functional layer 212a and a second functional layer 212c may be respectively disposed below and above the emission layer 212b. The first functional layer 212a may include a hole transport layer (“HTL”), or an HTL and a hole injection layer (“HIL”), for example. The second functional layer 212c, as a component disposed on the emission layer 212b, may be optional. The second functional layer 212c may include an electron transport layer (“ETL”) and/or an electron injection layer (“EIL”). Similar to the second electrode 213 to be described below, the first functional layer 212a and/or the second functional layer 212c may be a common layer formed to cover an entirety of the substrate 100.

The second electrode 213 may be disposed on the intermediate layer 212. The second electrode 213 may include a conductive material having a relatively low work function. In an embodiment, the second electrode 213 may include a (semi)transparent layer including Ag, Mg, Al, Pt, Pd, Au, Ni, Nd, Ir, Cr, Li, Ca, any alloys thereof, or the like, for example. In an alternative embodiment, the second electrode 213 may further include a layer, such as ITO, IZO, ZnO, or In₂O₃, above the (semi)transparent layer including the above-stated material.

In some embodiments, a capping layer (not shown) may be further disposed on the second electrode 213. The capping layer may include an inorganic material such as lithium fluoride (LiF), or/and an organic material.

The encapsulation layer ENL may be disposed on the second electrode 213. In an embodiment, the encapsulation layer ENL may include at least one inorganic encapsulation layer and at least one organic encapsulation layer. In an embodiment, FIG. 8 shows that the encapsulation layer ENL includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy resin, polyimide, polyethylene, or the like. In an embodiment, the organic encapsulation layer 320 may include acrylate.

The transparent organic material layer OCL may be disposed on the encapsulation layer ENL. The transparent organic material layer OCL may be an overcoat layer.

Although it has described with reference to FIG. 8 that a light-emitting diode, e.g., the first light-emitting diode LED1, is an organic light-emitting diode including an organic material, the disclosure is not limited thereto. The first light-emitting diode LED1 described with reference to FIG. 8 and the second and third light-emitting diodes LED2 and LED3 described above with reference to FIG. 7 may be inorganic light-emitting diodes each including an inorganic material. The inorganic light-emitting diode may include a PN junction diode including materials based on inorganic semiconductors. When a voltage is applied to the PN junction diode in a forward direction, holes and electrons may be injected, and energy generated by recombination of the holes and electrons may be converted into light energy to emit light of a predetermined color. The above-described inorganic light-emitting diode may have a length or width of several to several hundreds of micrometers, or several to several hundreds of nanometers. In some embodiments, the first to third light-emitting diodes LED1, LED2, and LED3 (refer to FIG. 7) may include quantum dot light-emitting diodes including quantum dots. As described above, an emission layer of each of the first to third light-emitting diodes LED1, LED2, and LED3 may include an organic material, an inorganic material, quantum dots, an organic material and quantum dots, or an inorganic material and quantum dots. The first to third light-emitting diodes LED1, LED2, and LED3 (refer to FIG. 7) may each have a bar shape or a rod shape. In an alternative embodiment, the first to third light-emitting diodes LED1, LED2, and LED3 (refer to FIG. 7) may have various shapes, such as a planar shape of a polygonal shape, an elliptical shape, or a circular shape, which has a predetermined area.

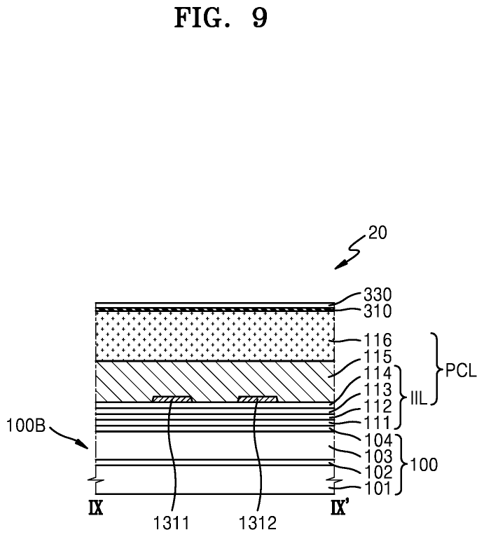

FIG. 9 is a cross-sectional view of the connection unit 20 taken along line IX-IX′ of FIG. 7.

Referring to FIG. 9, lines passing through the connection unit 20 may be disposed on the substrate 100. As described above with reference to FIG. 8, the substrate 100 may include the first base layer 101, the first barrier layer 102, the second base layer 103, and the second barrier layer 104. In an alternative embodiment, the substrate 100 may include metal, glass, or the like.

Referring to FIGS. 7 to 9, the shape of the display device 1 may be viewed as the shape of the substrate 100. The substrate 100 includes a first area 100A corresponding to the display unit 10 and a second area 100B corresponding to the connection unit 20. In an embodiment, the substrate 100 may include first areas 100A which are spatially spaced apart from each other and the second area 100B disposed between two adjacent first areas 100A and structurally connecting the two adjacent first areas 100A to each other, for example. The first area 100A and the second area 100B of the substrate 100 may be integrally unitary with each other. A particular shape of the second area 100B of the substrate 100 is the same as the shape of the connection unit 20 described above with reference to FIGS. 1 to 3.

In an embodiment, the second area 100B of the substrate 100 may include first parts disposed on a plane different from a plane where the first area 100A is disposed, and a second part disposed between the first parts and disposed on a plane different from the plane where the first area 100A is disposed, for example. The second part of the second area 100B of the substrate 100 may be disposed at a top part of the second area 100B. A hole 100H (refer to FIG. 7) corresponding to the hole 20H (refer to FIG. 7) of the connection unit 20 may be defined in the second area 100B of the substrate 100. In an embodiment, the hole 100H may be disposed in the second part of the second area 100B, for example. Among the descriptions made with reference to FIG. 7, the first and second lines 2311 and 2312 extending to pass through the first side of the hole 20H and the third to fifth lines 2313, 2314, and 2315 extending to pass through the second side (the opposite side of the first side) of the hole 20H may indicate that the first and second lines 2311 and 2312 extending to pass through a first side of the hole 100H of the second area 100B of the substrate 100 and the third to fifth lines 2313, 2314, and 2315 extending to pass through a second side (an opposite side of the first side) of the hole 100H of the second area 100B. Similarly, the sixth and seventh lines 1311 and 1312 extending to pass through the first side of the hole 20H and the eighth and ninth lines 1313 and 1314 extending to pass through the second side (the opposite side of the first side) of the hole 20H may indicate that the sixth and seventh lines 1311 and 1312 extending to pass through a first side of the hole 100H of the second area 100B of the substrate 100 and the eighth and ninth lines 1313 and 1314 extending to pass through the second side (the opposite side of the first side) of the hole 100H of the second area 100B of the substrate 100.

Lines, e.g., the sixth and seventh lines 1311 and 1312 shown in FIG. 9, are arranged in the second area 100B of the substrate 100, and may be disposed on the inorganic insulating layer IIL. The sixth and seventh lines 1311 and 1312 may be covered with an organic insulating material, e.g., the lower organic insulating layer 115 and the organic insulating layer 116. In an alternative embodiment, one of the lower organic insulating layer 115 and the organic insulating layer 116 may be omitted. In another embodiment, the lower organic insulating layer 115 and the organic insulating layer 116 may be omitted, and the sixth and seventh lines 1311 and 1312 may be covered with the first inorganic encapsulation layer 310 and the second inorganic encapsulation layer 330 without an organic insulating layer therebetween.

In an embodiment, as shown in FIG. 9, it is shown that the sixth and seventh lines 1311 and 1312 are disposed on the inter-insulating layer 114. In another embodiment, any one of the sixth and seventh lines 1311 and 1312 may be disposed on another inorganic insulating layer, e.g., the buffer layer 111, the first gate insulating layer 112, or the second gate insulating layer 113. FIG. 9 shows that the sixth and seventh lines 1311 and 1312 are disposed in the same layer, but in another embodiment, the sixth and seventh lines 1311 and 1312 may be disposed in different layers.

Although FIG. 9 shows the sixth and seventh lines 1311 and 1312, in another embodiment, other lines, e.g., first to fifth lines, and eighth and ninth lines may have the same structure described with reference to FIG. 9. In an embodiment, each of the first to fifth lines and the eighth and ninth lines may be disposed on any one inorganic insulating layer, for example. Also, the first to fifth lines and the eighth and ninth lines may be disposed in the same layer or may be disposed in different layers.

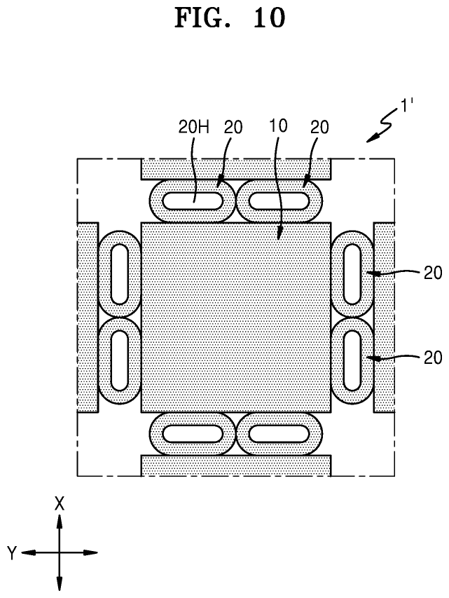

FIG. 10 is a plan view schematically illustrating the display device 1′. In the display device 1 described above with reference to FIG. 1, it is shown that one connection unit 20 is disposed between two adjacent display units 10, but the disclosure is not limited thereto.

In another embodiment, a plurality of connection units 20 may be arranged between two adjacent display units 10, and in this regard, FIG. 10 shows that two connection units 20 are arranged between two adjacent display units 10. The structure of each connection unit 20 is as described above. The connection units 20 arranged between two display units 10 may be connected to each other as shown in FIG. 10, or may be separated from each other. When the plurality of connection units 20 is arranged between two display units 10, stress due to stretching of the display device 1′ may be dispersed, and positions of lines providing signals or voltages may be further variously separated.

In an embodiment, a stretchable display device capable of being highly extended or highly stretched and having excellent durability may be provided. However, these effects are exemplary, and the scope of the disclosure is not limited thereto.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the claims.

What is claimed is:

1. A stretchable display device comprising:
a plurality of display units each comprising a light-emitting diode; and
a connection unit disposed between two adjacent display units among the plurality of display units and connected to each of the two adjacent display units,
wherein the connection unit includes a curved part curved in a direction perpendicular to an upper surface of a display unit of the plurality of display units and a hole is defined in the connection unit when viewed from the direction perpendicular to the upper surface of the display unit of the plurality of display units.

2. The stretchable display device of claim 1, wherein the connection unit comprises:
a pair of first parts respectively connected to the two adjacent display units; and
a second part disposed between the pair of first parts and disposed on a surface different from a surface where each of the pair of first parts is disposed.

3. The stretchable display device of claim 2, wherein, in each of the pair of first parts, a width of an area adjacent to the second part is greater than a width of an area adjacent to the display unit of the plurality of display units.

4. The stretchable display device of claim 2, wherein the pair of first parts and the second part are disposed on different surfaces from a surface where the display unit of the plurality of display units is disposed.

5. The stretchable display device of claim 1, wherein one of the two adjacent display units comprises a sub-pixel circuit electrically connected to the light-emitting diode of the one display unit and comprising a thin-film transistor and a capacitor, and
a plurality of lines electrically connected to the sub-pixel circuit and providing signals or voltages extend toward another one of the two adjacent display units by passing the connection unit.

6. The stretchable display device of claim 5, wherein the plurality of lines comprise a first line and a second line, and
the first line and the second line are disposed on opposite sides with respect to the hole of the connection unit.

7. The stretchable display device of claim 1, wherein a shape of the connection unit is changed and a curvature of the curved part is reduced when the stretchable display device is extended.

8. The stretchable display device of claim 1, wherein the hole of the connection unit has an elliptical shape.

9. The stretchable display device of claim 8, wherein a shape of the hole of the connection unit is changed from the elliptical shape to a circular shape when the stretchable display device is extended.

10. A stretchable display device comprising:
a substrate comprising a plurality of first areas and a second area between two adjacent first areas among the plurality of first areas;
a plurality of display units respectively corresponding to the plurality of first areas of the substrate and each comprising a light-emitting diode disposed in corresponding one of the plurality of first areas; and
a connection unit corresponding to the second area of the substrate,
wherein the connection unit includes a curved part curved in a direction perpendicular to an upper surface of a display unit of the plurality of display units and a hole is defined in the connection unit when viewed from the direction perpendicular to the upper surface of the display unit of the plurality of display units.

11. The stretchable display device of claim 10, wherein the second area of the substrate includes a curved part curved in the direction perpendicular to the upper surface of the display unit of the plurality of display units and a hole corresponding to the hole of the connection unit is defined in the second area of the substrate when viewed from the direction perpendicular to the upper surface of the display unit of the plurality of display units.

12. The stretchable display device of claim 11, wherein the connection unit comprises:
a pair of first parts respectively connected to two adjacent display units among the plurality of display units; and
a second part disposed between the pair of first parts and disposed on a surface different from a surface where each of the pair of first parts is disposed.

13. The stretchable display device of claim 12, wherein, in each of the pair of first parts, a width of an area adjacent to the second part is greater than a width of an area adjacent to the display unit of the plurality of display units.

14. The stretchable display device of claim 12, wherein one of the two adjacent display units comprises a sub-pixel circuit electrically connected to the light-emitting diode of the one display unit and comprising a thin-film transistor and a capacitor.

15. The stretchable display device of claim 14, wherein the connection unit comprises a plurality of lines disposed in the second area of the substrate, electrically connected to the sub-pixel circuit, and providing signals or voltages.

16. The stretchable display device of claim 15, wherein the plurality of lines comprise a first line and a second line, and
the first line and the second line are disposed on opposite sides with respect to the hole of the connection unit.

17. The stretchable display device of claim 10, wherein a shape of the connection unit is changed and a curvature of the curved part is reduced when the stretchable display device is extended.

18. The stretchable display device of claim 10, wherein the hole of the connection unit has an elliptical shape.

19. The stretchable display device of claim 18, wherein a shape of the hole of the connection unit is changed from the elliptical shape to a circular shape when the stretchable display device is extended.
